(19) United States
(12) Patent Application Publication
(10) Pub. No.: US 2022/0384690 A1
(43) Pub. Date: Dec. 1, 2022

(54) LED DISPLAY ASSEMBLY, METHOD FOR PROCESSING THE LED DISPLAY ASSEMBLY, AND LED DISPLAY SCREEN

(71) Applicant: FOSHAN NATIONSTAR OPTOELECTRONICS CO., LTD., Foshan (CN)

(72) Inventors: Kuai Qin, Foshan (CN); Heng Guo, Foshan (CN); Qiang Zhao, Foshan (CN); Hongwen Chen, Foshan (CN); Bin Cai, Foshan (CN); Junyong Wang, Foshan (CN); Nianpu Li, Foshan (CN); Xiaobo Ouyang, Foshan (CN)

(73) Assignee: FOSHAN NATIONSTAR OPTOELECTRONICS CO., LTD., Foshan (CN)

(21) Appl. No.: 17/748,493

(22) Filed: May 19, 2022

(30) Foreign Application Priority Data
May 28, 2021 (CN) 202110594731.3

(51) Int. Cl. H01L 33/48; H01L 25/075; H01L 33/62; H01L 33/00

(52) U.S. Cl. CPC H01L 33/486; H01L 25/0753; H01L 33/62; H01L 33/005; H01L 2933/0066

(57) ABSTRACT

Provided is a light-emitting diode (LED) display assembly. The LED display assembly includes a plurality of chips, a first carrier and a second carrier. Two opposite side surfaces of the first carrier are respectively a first mounting surface and a second mounting surface. The first mounting surface is provided with first pads, and the first pads are connected to the chips. The second mounting surface is provided with first pins, and wires in the first carrier connect the first pads to the first pins. An area of each of the first pins is larger than an area of each of the first pads. The second carrier is provided with a third mounting surface, the third mounting surface is provided with second pads whose number is the same as a number of the first pins, and the second pads are welded to the first pins in one-to-one correspondence.

### CROSS-REFERENCE TO RELATED APPLICATION

This application claims priority to Chinese Patent Application No. 202110594731.3 filed May 28, 2021, the disclosure of which is incorporated herein by reference in its entirety.

### TECHNICAL FIELD

The present disclosure relates to the field of light-emitting diode (LED) technologies and, in particular, to an LED display assembly, a method for processing the LED display assembly and an LED display screen including the LED display assembly.

### BACKGROUND

With the development of society, users need higher-resolution display screens, which require the increasingly smaller distance between light-emitting diode (LED) display points and increasingly higher product reliability. With the reduction of the distance between LED display points, the size of lamp beads needs to be reduced accordingly, and the size of chips used by the lamp beads will also continue to shrink. In the LED packaging industry, the smaller the size of chips, the higher the requirements for the working accuracy of a die-bonding device. Under this technical route, the biggest constraint on the development of LED display screens is the accuracy of the die-bonding device.

### SUMMARY

An objective of embodiments of the present disclosure is to provide a light-emitting diode (LED) display assembly with small gaps between chips.

Another objective of the embodiments of the present disclosure is to provide a method for processing an LED display assembly, which can reduce the difficulty of fixing chips with small gaps on a circuit board.

Another objective of the embodiments of the present disclosure is to provide an LED display assembly having relatively high resolution.

Technical solutions described below are adopted to achieve the above objects.

In a first aspect, an LED display assembly is provided. The LED display assembly includes a plurality of chips, a first carrier and a second carrier.

Two opposite side surfaces of the first carrier are respectively a first mounting surface and a second mounting surface, the first mounting surface is provided with a plurality of first pads, the plurality of first pads are connected to the chips, the second mounting surface is provided with a plurality of first pins, wires in the first carrier connect the plurality of first pads to the plurality of first pins, and an area of each of the plurality of first pins is larger than an area of each of the plurality of first pads.

The second carrier is provided with a third mounting surface, the third mounting surface is provided with second pads whose number is the same as a number of the plurality of first pins, and the second pads are welded to the plurality of first pins in one-to-one correspondence.

For example, a ratio of the area of the each of the plurality of first pins to the area of the each of the plurality of first pads is 4:1 to 10:1.

For example, the first carrier is a conductive plate; and the second carrier is a circuit board.

For example, at least one of the following applies: the first carrier is a silicon carbide plate or a silicon plate; or the second carrier is a printed circuit board (PCB).

For example, the chips are flip chips.

For example, at least one side of the first carrier away from the second carrier is provided with a package layer, and the chips are located in the package layer.

For example, at least one of the following applies: the first mounting surface around the plurality of first pads is provided with an ink layer; or the third mounting surface around the second pads is provided with an ink layer.

In a second aspect, a method for processing an LED display assembly is provided, the method being configured to process the above LED display assembly and including steps described below.

A plurality of chips are placed on a first mounting surface of a first carrier, each of the plurality of chips is respectively welded to a respective one of first pads of the first carrier, after all of the plurality of chips are welded to the first pads, the first carrier is placed on a third mounting surface of a second carrier, and first pins of the first carrier are welded to second pads of the second carrier.

For example, welding the each of the plurality of chips to the respective one of the first pads of the first carrier includes aligning the all of the plurality of chips with the first pads, and simultaneously welding the all of the plurality of chips to the first pads.

For example, aligning the all of the plurality of chips with the first pads includes transferring a plurality of chips to the first mounting surface by using laser mass transfer technology so that the all of the plurality of chips are aligned with the first pads.

For example, the plurality of chips are welded to the first pads by adopting an eutectic-welding manner.

For example, at least one of the following applies: the method further includes after the plurality of chips are welded to the first pads and before the first carrier is welded to the second carrier, packaging the first mounting surface by using packaging adhesive to form a package layer; or the method further includes: after the first carrier is welded to the second carrier, packaging the first carrier and the second carrier as a whole by using packaging adhesive.

For example, before the plurality of chips are placed on the first mounting surface, the method further includes coating the first mounting surface with ink to form an ink layer.

In a third aspect, an LED display screen is provided, and the LED display screen includes the above LED display assembly.

The present disclosure has beneficial effects described below. Due to the relatively-small size of the chips and the simple circuit structure of the first carrier, the gap between adjacent two chips can be reduced by reducing the distance between adjacent two first pins. Moreover, since the circuit structure of the second carrier is complex and the machining accuracy of the second carrier is relatively low it is difficult to reduce the gap between adjacent two second pads, the area of each first pin on the first carrier is larger than the area of each first pad, thus after the chips are welded to the first carrier, in the circuit structure, the first pins are the extension of the chips, and providing the first carrier is equivalent to increasing the size of the pins of the chips, so that the difficulty of welding the chips to the second carrier is reduced.

### BRIEF DESCRIPTION OF DRAWINGS

The present disclosure will be further described in detail according to the drawings and embodiments.

FIG. 1 is a side view of an LED display assembly according to an embodiment of the present disclosure;

FIG. 2 is a front view of an LED display assembly according to an embodiment of the present disclosure (a package layer is not shown);

FIG. 3 is a front view of a first carrier according to an embodiment of the present disclosure;

FIG. 4 is a rear view of a first carrier according to an embodiment of the present disclosure;

FIG. 5 is a side view of a first carrier according to an embodiment of the present disclosure;

FIG. 6 is a front view of a first carrier according to another embodiment of the present disclosure;

FIG. 7 is a rear view of a first carrier according to another embodiment of the present disclosure;

FIG. 8 is a front view of a second carrier according to an embodiment of the present disclosure;

FIG. 9 is a rear view of a second carrier according to an embodiment of the present disclosure;

FIG. 10 is a sectional view of a second carrier according to an embodiment of the present disclosure;

FIG. 11 is a front view of a second carrier according to another embodiment of the present disclosure; and

FIG. 12 is a rear view of a second carrier according to another embodiment of the present disclosure.

### REFERENCE LIST

1 first carrier
11 pad group
101 first pad
102 first pin
103 first through hole
104 wire
2 second carrier
201 second pad
202 second pin
203 second through hole
3 chip
4 package layer

### DETAILED DESCRIPTION

To make solved problems, adopted solutions and achieved effects of the present disclosure clearer, the solution of the present disclosure is further described in conjunction with the drawings and embodiments. The embodiments described below are part, not all, of embodiments of the present disclosure. Based on the embodiments of the present disclosure, all other embodiments obtained by those skilled in the art are within the scope of the present disclosure on the premise that no creative work is done.

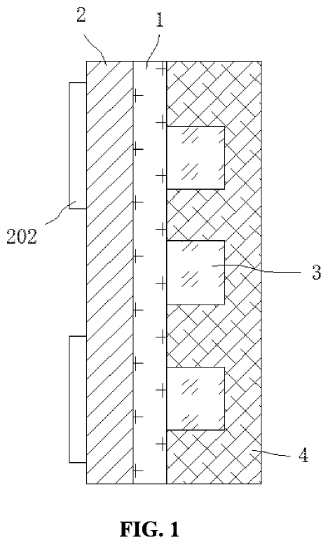

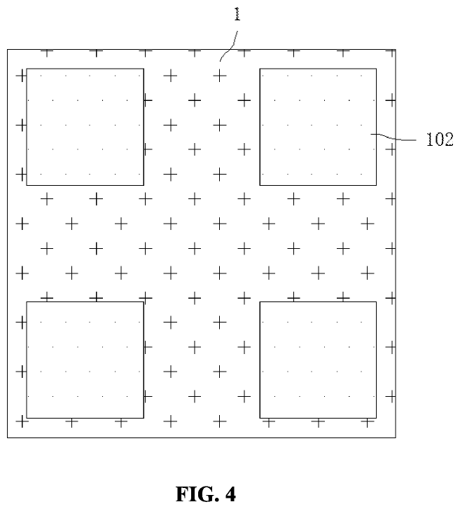

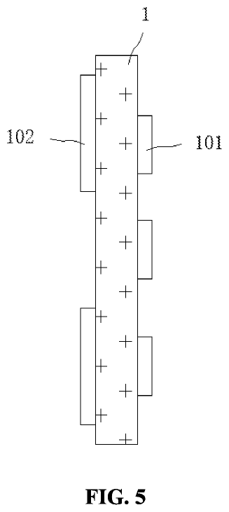

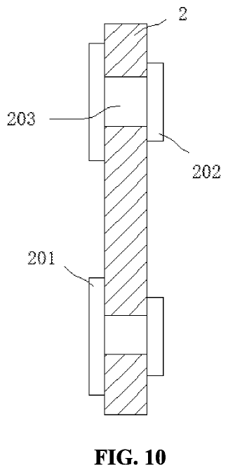

As shown in FIGS. 1 to 5 and FIG. 10, the present disclosure provides a light-emitting diode (LED) display assembly. The LED display assembly includes chips 3, a first carrier 1 and a second carrier 2. At least two chips 3 are provided. Two opposite side surfaces of the first carrier 1 are respectively a first mounting surface and a second mounting surface, the first mounting surface is provided with a plurality of first pads 101, the plurality of first pads 101 are welded to the chips 3, the second mounting surface is provided with a plurality of first pins 102, wires in the first carrier 1 connect the plurality of first pads 101 to the plurality of first pins 102, and an area of each of the plurality of first pins 102 is larger than an area of each of the plurality of first pads 101. The second carrier 2 is provided with a third mounting surface, the third mounting surface is provided with second pads 201 whose number is the same as a number of the plurality of first pins 102, and the second pads 201 are welded to the plurality of first pins 102 in one-to-one correspondence. Due to the relatively-small size of the chips 3 and the simple circuit structure of the first carrier 1, the gap between adjacent two chips 3 can be reduced by reducing the distance between adjacent two first pins 102; since the circuit structure of the second carrier 2 is complex and the machining accuracy of the second carrier 2 is relatively low it is difficult to reduce the gap between adjacent two second pads 201, the area of each first pin 102 on the first carrier 1 is larger than the area of each first pad 101, thus after chips 3 are welded to the first carrier 1, in the circuit structure, the first pins 102 are the extension of the chips 3, and providing the first carrier 1 is equivalent to increasing the size of the pins of the chips 3, so that the difficulty of welding the chips 3 to the second carrier 2 is reduced.

For example, a ratio of the area of each first pin 102 to the area of each first pad 101 is 4:1 to 10:1. In the embodiment, the size of the chips 3 is 0.05 mm*0.1 mm, and the size of the first carrier 1 is 0.23 mm*0.15 mm. Since the first pins 102 are equivalent to the enlarged pins of the chips 3, the area ratio between the first pin 102 and the first pad 101 is ensured to be 4:1 to 10:1 so that the function of the first carrier 1 can be better achieved.

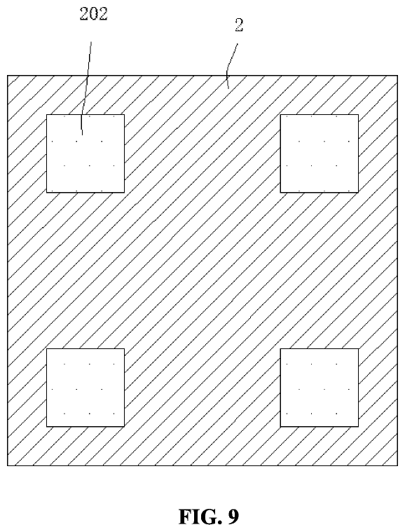

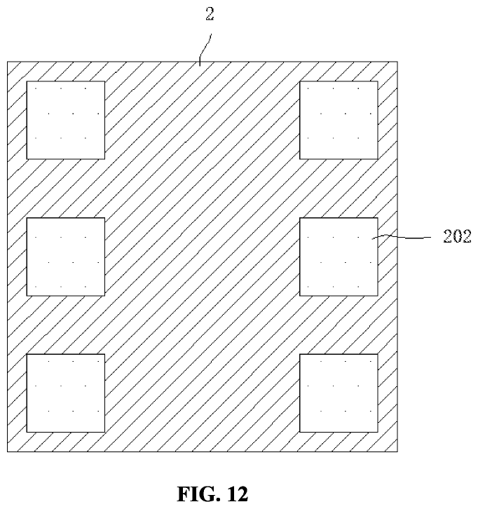

Referring to FIG. 9 and FIG. 12, for example, the second carrier 2 is provided with a fourth mounting surface, the fourth mounting surface is opposite to the third mounting surface, and the fourth mounting surface is provided with second pins 202. Through the second pins 202, the second carrier 2 can be conveniently connected to an external circuit.

In the embodiment, the LED display assembly is applied to an LED display screen. The distance between two connected chips 3 is reduced, so that the resolution of the display screen can be improved, and the picture effect can be improved.

For example, the first carrier 1 is a conductive plate; and the second carrier 2 is a circuit board. In the embodiment, the chips 3 are Micro LED chips, the size of the chips 3 is 0.05 mm*0.1 mm, and the size of the first carrier 1 is 0.23 mm*0.15 mm. The circuit structure of the circuit board is complicated, and the size of the chips 3 is relatively small. The first carrier 1 is provided and used for connecting the chips 3 to the second carrier 2, which can reduce the difficulty of connecting the chips 3 to the circuit board, prevent the circuit structure of the second carrier 2 from being complicated, and reduce the processing difficulty of the second carrier 2.

In the embodiment, the chips 3 are flip chips, the first carrier 1 is a silicon carbide plate, and the second carrier 2 is a printed circuit board (PCB). Silicon carbide has characteristics of corrosion resistance, high temperature resistance, high strength, good thermal conductivity, and impact resistance. Therefore, the first carrier 1 can conduct heat for the working chips 3 to ensure the normal operation of the chips 3. Of course, the first carrier 1 may also be a silicon plate or a plate made of other silicon materials.

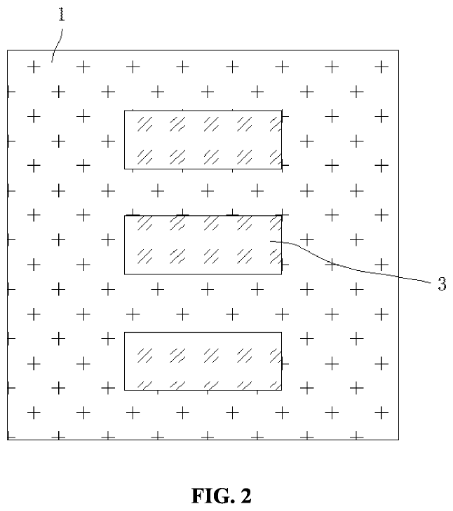

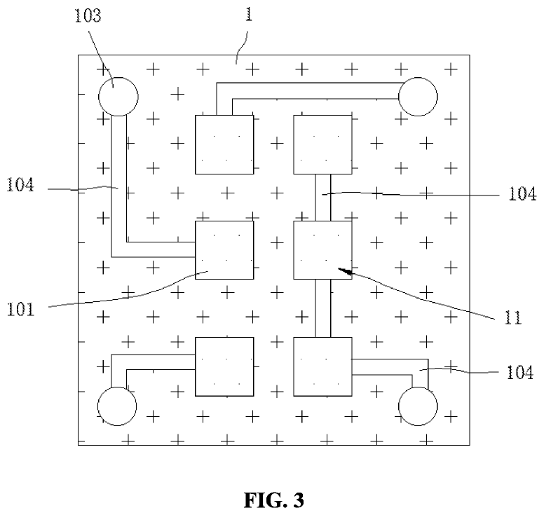

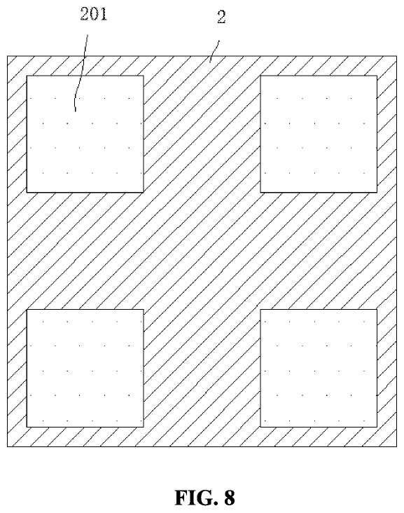

For example, referring to FIG. 2, one LED display assembly is provided with one chipset, and the one chipset contains three chips 3 which are respectively a red-light chip, a green-light chip and a blue light-chip. Referring to FIGS. 3 to 5, in the embodiment, one first carrier 1 is provided with six first pads 101 and four first pins 102, and three of the six first pads 101 are connected by wires 104 to form a pad group 11; of course, the size of the three first pads 101 may also be directly increased until the three first pads 101 are connected to each other to form the pad group 11. The pad group 11 is connected to one of the four first pins 102, and the remaining three first pads 101 are connected to the remaining three first pins 102 in one-to-one correspondence. Referring to FIGS. 8 to 10, the second carrier 2 is correspondingly provided with four second pads 201 and four second pins 202. The pad group 11 is provided, so that three chips 3 in each chipset can be integrated. At this time, the chipset can be uniformly controlled and the circuit structure can be simplified.

In the embodiment, the distance between adjacent two chips 3 in each chipset is not greater than 40 microns. The distance between the chips is reduced, so that the graininess of display pixels of the LED display screen can be reduced, and the display effect of the LED display screen can be improved.

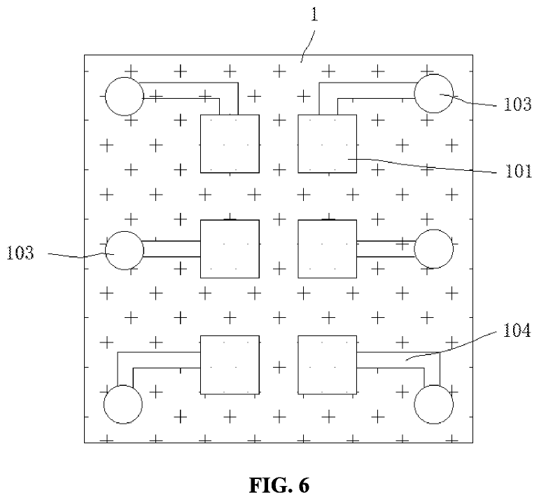

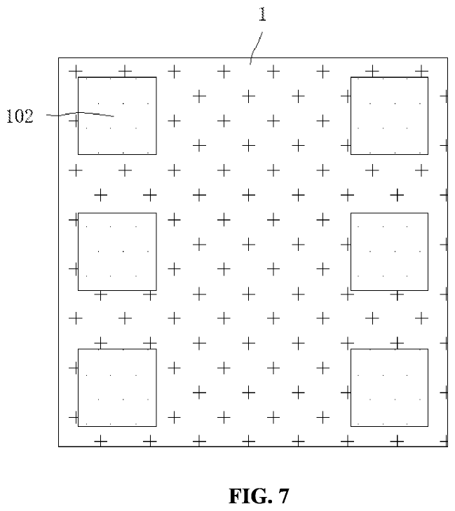

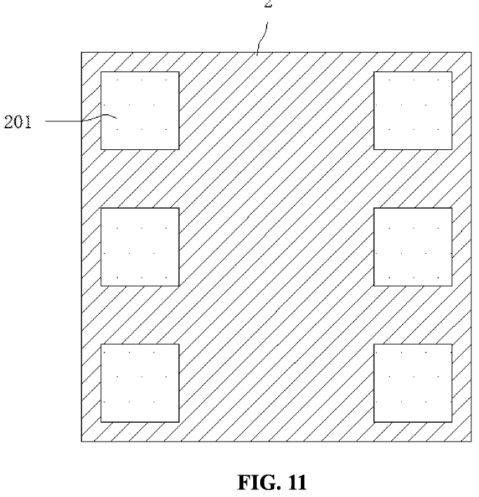

Referring to FIGS. 6 and 7, in other embodiments, one first carrier 1 is provided with six first pads 101 and six first pins 102, and one first pad 101 is connected by a wire 104 to one first pin 102. Referring to FIGS. 11 and 12, the second carrier 2 is correspondingly provided with six second pads 201 and six second pins 202. At this time, the chips 3 in the chipset can be individually controlled, so that the chipset can emit more colors of light, and the picture effect of the LED display screen is improved.

For example, the first carrier 1 is provided with first through holes 103. In an embodiment, one end of the wire 104 is connected to the first pin 102, and the other end passes through the first through hole 103 and is connected to the first pad 101. Since the size of the first carrier 1 is relatively small, the first through hole 103 is provided and the wire 104 passes through the first through hole 103 to connect the first pin 102 and the first pad 101, so that the processing difficulty of the first carrier 1 can be reduced, and the production cost can be reduced.

For example, in other embodiments, the wall of the first through hole 103 is provided with a conductive layer, the first pin 102 is connected to the conductive layer, one end of the wire 104 is connected to the first pad 101, and the other end is connected to the conductive layer; of course, the first pad 101 may also be connected to the conductive layer, and at this time, two ends of the wire 104 are respectively connected to the first pin 102 and the conductive layer. The size of the first carrier 1 is relatively small, and correspondingly, the size of the wire 104 is relatively small. The conductive layer is provided, so that the number of times that the wire 104 is bent can be reduced, and the wire 104 is prevented from being broken and thus causing circuit failure.

For example, the second carrier 2 is provided with second through holes 203. The wall of the second through hole 203 is provided with a conductive layer, and the second pad 201 is connected to the second pin 202 through the conductive layer. In the embodiment, the second carrier 2 is a PCB. The second through hole 203 is provided and connects the second pad 201 and the second pin 202, so that the circuit structure of the second carrier 2 can be simplified, and the processing cost of the second carrier can be reduced.

For example, at least one side of the first carrier 1 away from the second carrier 2 is provided with a package layer 4, and the chips 3 in the chipset are located in the package layer 4. Since the size of the chips 3 and the size of the first pads 101 are relatively small, the connection strength produced by the welding of the chips 3 and the first pads 101 is relatively small. The package layer 4 is provided, so that the stability of the connection between the chips 3 and the first carrier 1 can be improved, and poor contact between the chips 3 and the first carrier 1 can be avoided.

For example, the first mounting surface around the first pads 101 is provided with an ink layer, so that the contrast of the LED display screen can be improved, and the picture effect of the LED display screen can be improved.

In an embodiment, the third mounting surface around the second pads 201 is further provided with an ink layer. It is to be understood that the higher the percentage of black region area of the LED display assembly, the higher the contrast of the LED display screen. In the embodiment, the percentage of black region area of the whole LED display assembly is not less than 85%, which can help improve the display effect of the LED display screen.

For example, the area of the first mounting surface of the first carrier 1 is the same as the area of the third mounting surface of the second carrier 2. Therefore, the package layer 4 only needs to package the first mounting surface to complete the packaging of the LED display assembly.

The present disclosure further provides a method for processing an LED display assembly, the method being configured to process the LED display assembly of the above embodiments and including steps described below.

A plurality of chips 3 are placed on a first mounting surface of a first carrier 1, each of the plurality of chips 3 is welded to a respective one of the first pads 101 of the first carrier 1, after all of the plurality of chips 3 are welded to the first pads 101, the first carrier 1 is placed on a third mounting surface of a second carrier 2, and then first pins 102 of the first carrier 1 are welded to second pads 201 of the second carrier 2.

The chips 3 are first welded to the first carrier 1, so that the difficulty of positioning between the chips 3 and the first carrier 1 can be reduced, and thus the difficulty of welding the chips 3 and the first carrier 1 can be reduced. After the chips 3 are welded to the first pads 101, the first pins 102 connected to the first pads 101 can serve as pin extension structures of the chips 3. At this time, the first carrier 1 is welded to the second carrier 2, and thus the difficulty of connecting the chips 3 and the second carrier 2 is reduced.

For example, in the embodiment, after the all of the plurality of chips 3 are aligned with the first pads 101, the all of the plurality of chips are simultaneously welded to the first pads 101. In the embodiment, the chips 3 are transferred to the first carrier 1 by using laser mass transfer technology. For example, the laser mass transfer technology includes steps described below. Multiple chips 3 are first arranged and fixed on a first substrate, where the first substrate is provided with multiple hollow structures and the chips 3 are clamped in the hollow structures. The first mounting surface of the first carrier 1 is placed upward, the first substrate is moved to above the first mounting surface, and then the chips are separated from the substrate by using laser. At this time, the chips 3 fall on the first mounting surface under the action of gravity. To reduce the workload of aligning the chips 3 with the first pads 101, the chips 3 may be arranged on the first substrate in a certain order and at certain intervals. At this time, when the chips 3 fall on the first mounting surface, the chips 3 can be aligned with the first pads 101, so that the workload of the welding operation is reduced, and the efficiency of welding is improved. In the embodiment, a group of chipsets are arranged on the first substrate, three chips 3 can be simultaneously welded in one time of welding operation, and thus the welding efficiency is three times the efficiency of conventional welding.

For example, the plurality of chips 3 are welded to the first pads 101 by adopting an eutectic-welding manner. The eutectic temperature is greater than 300 degrees Celsius. The first pads 101 may be first coated with eutectic solder. The eutectic solder is high-melting-point solder, and gold silicide, gold germanium and the like may be selected. Then, the first pads 101 coated with the eutectic solder is coated with flux, and then the chips 3 are flipped. After the chips 3 are aligned with the first pads 101, the eutectic solder on the first pads 101 is melted to be connected to the chips 3. Since the size of the chips 3 and the size of the first pads 101 are relatively small, the stability of the connection between the chips 3 and the first pads 101 can be ensured by adopting the eutectic-welding manner, and welding defects caused by the welding process can be avoided.

For example, eutectic welding may be adopted between the first carrier 1 and the second carrier 2, or reflow welding may also be adopted between the first carrier 1 and the second carrier 2, and of course, other suitable welding manners may also be selected for the first carrier 1 and the second carrier 2. The area of the first pin 102 is larger than the area of the first pad 101, while the welding region between the first carrier 1 and the second carrier 2 is relatively large, in the embodiment, reflow welding is used between the first carrier 1 and the second carrier 2, so that the manufacturing cost of the LED display assembly can be reduced.

In an embodiment, after the plurality of chips 3 are welded to the first pads 101 and before the first carrier 1 is welded to the second carrier 2, the first mounting surface is packaged by using packaging adhesive to form a package layer 4. In this way, the protection time of the package layer 4 to the chips 3 can be prolonged, and the welding operation of the first carrier 1 and the second carrier 2 can be prevented from affecting the connection between the chips 3 and the first pads 101.

In another embodiment, after the first carrier 1 is welded to the second carrier 2, another time of packing operation is performed. That is to say, in the embodiment, after the chips 3 are welded to the first pads 101, the first carrier 1 is first packaged, then the first carrier 1 is welded to the second carrier 2, and then the welded first carrier 1 and carrier 2 are packaged as a whole. In this way, the stability of the connection between the first carrier 1 and the second carrier 2 can be improved. In other embodiments, only the welded first carrier 1 and second carrier 2 may be packaged as a whole, which can reduce the processing steps of the LED device and reduce the production cost.

For example, in the embodiment, multiple first carriers 1 are arranged in an array on a second substrate, and the second substrate is provided with multiple hollow structures. The first carriers 1 are clamped in the hollow structures of the second substrate, so that the first mounting surface and the second mounting surface of the first carrier 1 can both be exposed from two sides of the second substrate. Multiple second carriers 2 are further correspondingly arranged in an array on a third substrate, and similarly, the third substrate is further provided with multiple hollow structures. The second carriers 2 are clamped in the hollow structures, so that the third mounting surface and the fourth mounting surface of the second carrier 2 can be exposed from two sides of the third substrate. The third substrate is placed on the second substrate, the multiple first carriers 1 are aligned with the multiple second carriers 2 respectively, and then the multiple second carriers 2 are simultaneous welded to the multiple first carriers 1. After the first pins 102 of the first carrier 1 are welded to the second pads 201 of the second carrier 2, a cutter is used to cut along the outer periphery of the first carriers 1, so that the LED display assembly can be mass-produced, and the productivity can be improved.

For example, the first mounting surface needs to be provided with an ink layer to improve the contrast of the LED display screen. In the embodiment, the first mounting surface of the first carrier 1 is coated with ink to form an ink layer, and then the chips 3 are placed on the first mounting surface. In this way, the difficulty of ink coating of the first mounting surface can be reduced, and at the same time, the ink can be prevented from adhering to the surface of the chips 3, thus avoiding the ink from affecting the light emission effect of the chips 3.

For example, the second carrier 2 also needs to be provided with an ink layer. Therefore, the second carrier 2 may be coated with ink to form an ink layer, and then the first carrier 1 is welded to the second carrier 2. In this way, the difficulty of ink coating of the second carrier 2 can be reduced.

What is claimed is:

1. A light-emitting diode (LED) display assembly, comprising:
a plurality of chips;
a first carrier, wherein two opposite side surfaces of the first carrier are respectively a first mounting surface and a second mounting surface, the first mounting surface is provided with a plurality of first pads, the plurality of first pads are connected to the plurality of chips, the second mounting surface is provided with a plurality of first pins, wires in the first carrier connect the plurality of first pads to the plurality of first pins, and an area of each of the plurality of first pins is larger than an area of each of the plurality of first pads; and
a second carrier, wherein the second carrier is provided with a third mounting surface, the third mounting surface is provided with second pads whose number is the same as a number of the plurality of first pins, and the second pads are welded to the plurality of first pins in one-to-one correspondence.

2. The LED display assembly according to claim 1, wherein a ratio of the area of the each of the plurality of first pins to the area of the each of the plurality of first pads is 4:1 to 10:1.

3. The LED display assembly according to claim 1, wherein the first carrier is a conductive plate, and the second carrier is a circuit board.

4. The LED display assembly according to claim 3, wherein at least one of the following applies:
the first carrier is a silicon carbide plate or a silicon plate; or
the second carrier is a printed circuit board (PCB).

5. The LED display assembly according to claim 1, wherein the plurality of chips are flip chips.

6. The LED display assembly according to claim 1, wherein at least one side of the first carrier away from the second carrier is provided with a package layer, and the plurality of chips are located in the package layer.

7. The LED display assembly according to claim 1, wherein at least one of the following applies:
the first mounting surface around the plurality of first pads is provided with an ink layer; or
the third mounting surface around the second pads is provided with an ink layer.

8. A method for processing a light-emitting diode (LED) display assembly, the method being configured to process an LED display assembly and comprising:
placing a plurality of chips on a first mounting surface of a first carrier, welding each of the plurality of chips to a respective one of first pads of the first carrier, after all of the plurality of chips are welded to the first pads, placing the first carrier on a third mounting surface of a second carrier, and welding first pins of the first carrier to second pads of the second carrier;
wherein the LED display assembly comprises:
the plurality of chips;
the first carrier, wherein two opposite side surfaces of the first carrier are respectively a first mounting surface and a second mounting surface, the first mounting surface is provided with the plurality of first pads, the plurality of first pads are connected to the plurality of chips, the second mounting surface is provided with the plurality of first pins, wires in the first carrier connect the plurality of first pads to the plurality of first pins, and an area of each of the plurality of first pins is larger than an area of each of the plurality of first pads; and
the second carrier, wherein the second carrier is provided with the third mounting surface, the third mounting surface is provided with the second pads whose number is the same as a number of the plurality of first pins, and the second pads are welded to the plurality of first pins in one-to-one correspondence.

9. The method for processing the LED display assembly according to claim 8, wherein welding the each of the plurality of chips to the respective one of the first pads of the first carrier comprises: aligning the all of the plurality of chips with the first pads, and simultaneously welding the all of the plurality of chips to the first pads.

10. The method for processing the LED display assembly according to claim 9, wherein aligning the all of the plurality of chips with the first pads comprises: transferring the plurality of chips to the first mounting surface by using laser mass transfer technology so that the all of the plurality of chips are aligned with the first pads.

11. The method for processing the LED display assembly according to claim 8, wherein the plurality of chips are welded to the first pads by adopting an eutectic-welding manner.

12. The method for processing the LED display assembly according to claim 8, wherein at least one of the following applies:
the method further comprises: after the plurality of chips are welded to the first pads and before the first carrier is welded to the second carrier, packaging the first mounting surface by using packaging adhesive to form a package layer; or
the method further comprises: after the first carrier is welded to the second carrier, packaging the first carrier and the second carrier as a whole by using packaging adhesive.

13. The method for processing the LED display assembly according to claim 8, before the plurality of chips are placed on the first mounting surface, the method further comprising: coating the first mounting surface with ink to form an ink layer.

14. A light-emitting diode (LED) display screen, comprising an LED display assembly, wherein the LED display assembly comprises:
a plurality of chips;
a first carrier, wherein two opposite side surfaces of the first carrier are respectively a first mounting surface and a second mounting surface, the first mounting surface is provided with a plurality of first pads, the plurality of first pads are connected to the plurality of chips, the second mounting surface is provided with a plurality of first pins, wires in the first carrier connect the plurality of first pads to the plurality of first pins, and an area of each of the plurality of first pins is larger than an area of each of the plurality of first pads; and
a second carrier, wherein the second carrier is provided with a third mounting surface, the third mounting surface is provided with second pads whose number is the same as a number of the plurality of first pins, and the second pads are welded to the plurality of first pins in one-to-one correspondence.

15. The LED display screen according to claim 14, wherein a ratio of the area of the each of the plurality of first pins to the area of the each of the plurality of first pads is 4:1 to 10:1.

16. The LED display screen according to claim 14, wherein the first carrier is a conductive plate, and the second carrier is a circuit board.

17. The LED display screen according to claim 16, wherein at least one of the following applies:
the first carrier is a silicon carbide plate or a silicon plate; or
the second carrier is a printed circuit board (PCB).

18. The LED display screen according to claim 14, wherein the plurality of chips are flip chips.

19. The LED display screen according to claim 14, wherein at least one side of the first carrier away from the second carrier is provided with a package layer, and the plurality of chips are located in the package layer.

20. The LED display screen according to claim 14, wherein at least one of the following applies:
the first mounting surface around the plurality of first pads is provided with an ink layer; or
the third mounting surface around the second pads is provided with an ink layer.
